(19) United States
(12) Patent Application Publication
(10) Pub. No.: US 2025/0127024 A1
(43) Pub. Date: Apr. 17, 2025

(54) PANEL BOTTOM MEMBER, DISPLAY DEVICE INCLUDING THE SAME, AND METHOD FOR MANUFACTURING THE DISPLAY DEVICE

(71) Applicant: Samsung Display Co., LTD., Yongin-si (KR)

(72) Inventors: JAESUK YOO, Yongin-si (KR); HUI YEON SHON, Yongin-si (KR); HYUN JOON OH, Yongin-si (KR); JAESANG LEE, Yongin-si (KR); JEE-NA LEE, Yongin-si (KR); KWANGSIG JUNG, Yongin-si (KR)

(21) Appl. No.: 18/901,295

(22) Filed: Sep. 30, 2024

(30) Foreign Application Priority Data
Oct. 16, 2023 (KR) 10-2023-0137969

(51) Int. Cl. H10K 59/80

(52) U.S. Cl. CPC H10K 59/8794; H10K 59/8792

(57) ABSTRACT

A panel bottom member includes: a base layer, a first adhesive layer disposed on the base layer, and a heat dissipation layer disposed in the first adhesive layer. The first adhesive layer includes a light-blocking material, a first surface of the first adhesive layer faces the base layer, and an embossing pattern is defined on a second surface of the first adhesive layer which is opposite to the first surface.

This application claims priority to Korean Patent Application No. 10-2023-0137969, filed on Oct. 16, 2023, and all the benefits accruing therefrom under 35 U.S.C. § 119, the content of which in its entirety is herein incorporated by reference.

### BACKGROUND

### 1. Field

Embodiments relate to a panel bottom member, display device including the panel bottom member, and a method for manufacturing the display device.

### 2. Description of the Related Art

A display device is a device that displays an image for providing visual information to a user. Among display devices, an organic light emitting diode display has recently attracted attention.

The display device may include a display panel and a panel bottom member. The display panel may include a plurality of pixels. Each of the plurality of pixels may emit light. The panel bottom member may perform various functions, such as protecting the display panel from external impact and emitting heat generated from the display panel.

### SUMMARY

Embodiments provide a panel bottom member with a simplified structure and reduced manufacturing costs.

Embodiments provide a display device including the panel bottom member.

Embodiments provide a method for manufacturing the display device.

A panel bottom member according to an embodiment includes a base layer, a first adhesive layer disposed on the base layer, where the first adhesive layer includes a light-blocking material, a first surface of the first adhesive layer faces the base layer and a second surface opposite to the first surface, and an embossing pattern is defined on the second surface of the first adhesive layer which is opposite to the first surface, and a heat dissipation layer disposed in the first adhesive layer.

In an embodiment, a plurality of openings may be defined in the heat dissipation layer and the first adhesive layer fills the plurality of openings of the heat dissipation layer.

In an embodiment, the heat dissipation layer may include graphite.

In an embodiment, the heat dissipation layer may be spaced apart from each of the first surface of the first adhesive layer and the second surface of the first adhesive layer in cross-sectional view.

In an embodiment, a distance between the heat dissipation layer and the first surface of the first adhesive layer may be less than a distance between the heat dissipation layer and the second surface of the first adhesive layer.

In an embodiment, the light-blocking material may include carbon black.

In an embodiment, a content of the light-blocking material in the first adhesive layer may be about 1.5 weight percent or greater and about 2 weight percent or less.

In an embodiment, an optical density of the first adhesive layer may be about 3.0 or greater.

In an embodiment, the base layer may include an acrylic foam material or a urethane-based foam material.

In an embodiment, the panel bottom member may further include a metal layer disposed under the base layer, and a second adhesive layer disposed between the base layer and the metal layer.

In an embodiment, the metal layer may include copper.

A display device according to an embodiment includes a display panel including a plurality of pixels and a panel bottom member disposed under the display panel.

In such an embodiment, the panel bottom member includes a base layer, a first adhesive layer disposed between the base layer and the display panel, where the first adhesive layer includes a light-blocking material, a first surface of the first adhesive layer faces the base layer, and an embossing pattern is defined on the second surface of the first adhesive layer which is opposite to the first surface, and heat dissipation layer disposed in the first adhesive layer.

In an embodiment, a plurality of openings may be defined in the heat dissipation layer, the first adhesive layer may fill the plurality of openings of the heat dissipation layer, and the heat dissipation layer may be spaced apart from each of the first surface of the first adhesive layer and a second surface of the first adhesive layer in cross-sectional view

A method for manufacturing a display device includes forming a panel bottom member and attaching the panel bottom member to a lower portion of the display panel.

In such an embodiment, the forming the panel bottom member includes forming a heat dissipation layer, in which a plurality of openings are defined, on a first adhesive resin layer, forming a second adhesive resin layer on the first adhesive resin layer to cover the heat dissipation layer, forming an embossing pattern on an upper surface of the second adhesive resin layer, and forming a base layer under the first adhesive resin layer.

In an embodiment, each of the first adhesive resin layer and the second adhesive resin layer may include a light-blocking material.

In an embodiment, in the forming the second adhesive resin layer, the second adhesive resin layer may fill the plurality of openings of the heat dissipation layer.

In an embodiment, the first adhesive resin layer may be formed on a first release film.

In an embodiment, the forming the base layer under the first adhesive resin layer may include attaching the base layer to a lower portion of the first adhesive resin layer after removing the first release film from the first adhesive resin layer.

In an embodiment, the forming the embossing pattern on the upper surface of the second adhesive resin layer may include attaching a second release film including a plurality of protrusions protruding toward the second adhesive resin layer to the second adhesive resin layer.

In an embodiment, the forming of the embossing pattern on the upper surface of the second adhesive resin layer may further include aging the second adhesive resin layer to which the second release film is attached for a preset period.

In an embodiment, the forming the embossing pattern on the upper surface of the second adhesive resin layer may further include removing the second release film from the second adhesive resin layer before the attaching the panel bottom member to the lower portion of the display panel.

A panel bottom member according to an embodiment includes a base layer, a first adhesive layer disposed on the base layer, where the first adhesive layer includes a light-blocking material, a first surface of the first adhesive layer faces the base layer, and an embossing pattern is defined on the second surface of the first adhesive layer which is opposite to the first surface, and a heat dissipation layer disposed in the first adhesive layer.

Accordingly, the first adhesive layer may reduce an amount of light incident on a lower surface of the display panel. In addition, the first adhesive layer may dissipate heat generated from the display panel. In addition, when the panel bottom member is attached to the lower portion of the display panel, bubbles may not be generated. In addition, the structure of the panel bottom member including the first adhesive layer may be simplified and manufacturing cost of the panel bottom member may be reduced.

### BRIEF DESCRIPTION OF THE DRAWINGS

Illustrative, non-limiting embodiments will be more clearly understood from the following detailed description in conjunction with the accompanying drawings.

FIG. 1 is a plan view illustrating a display device according to an embodiment.

FIG. 2 is a cross-sectional view illustrating a stacked structure of the display device of FIG. 1.

FIG. 3 is a cross-sectional view illustrating a panel bottom member included in the display device of FIG. 2.

FIG. 4 is a cross-sectional view illustrating a first adhesive layer included in the panel bottom member of FIG. 3.

FIG. 5 is a plan view illustrating the first adhesive layer of FIG. 4.

FIG. 6 is a cross-sectional view illustrating a pixel of FIG. 1.

FIGS. 7, 8, 9, 10, 11, 12, 13, and 14 are cross-sectional views illustrating an embodiment of a method for manufacturing the display device of FIG. 2.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art. Like reference numerals refer to like elements throughout.

It will be understood that when an element is referred to as being “on” another element, it can be directly on the other element or intervening elements may be present therebetween. In contrast, when an element is referred to as being “directly on” another element, there are no intervening elements present.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, display devices in accordance with embodiments will be described in more detail with reference to the accompanying drawings. The same or like reference numerals are used for the same or like components in the drawings, and any repetitive detailed descriptions of the same or like components will be omitted.

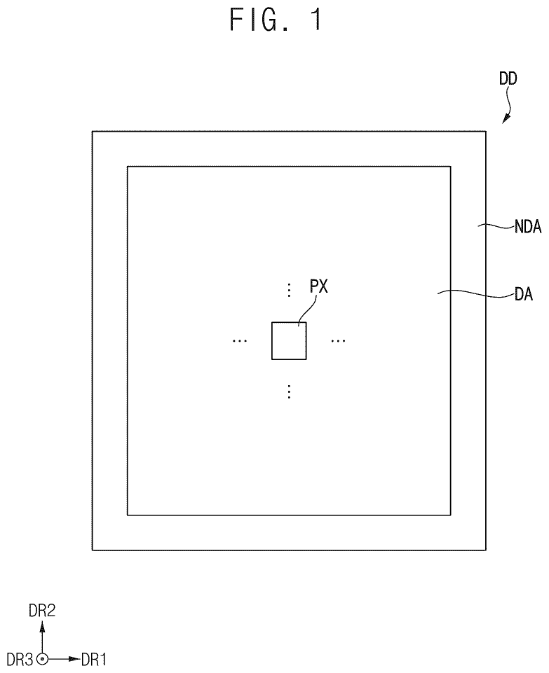

FIG. 1 is a plan view illustrating a display device according to an embodiment.

Referring to FIG. 1, a display device DD according to an embodiment may include a display area DA and a non-display area NDA. The display area DA may be defined as an area capable of displaying an image by generating light or adjusting a transmittance of light provided from an external light source. The non-display area NDA may be an area that does not display an image. In an embodiment, the non-display area NDA may surround at least a portion of the display area DA.

A plurality of pixels may be disposed in the display area DA. In an embodiment, for example, a pixel PX may be disposed in the display area DA. The plurality of pixels may be repeatedly arranged in a first direction DR1 and a second direction DR2 crossing the first direction DR1.

A driving unit may be disposed in the non-display area NDA. The driving unit may provide a signal or a voltage to the plurality of pixels. In an embodiment, for example, the driving unit may include a data driving unit, a gate driving unit, or the like.

In the disclosure, the first direction DR1 and the second direction DR2 crossing the first direction DR1 may be directions defined on a plane on which an image is displayed. In addition, a third direction DR3 perpendicular to a plane formed by the first direction DR1 and the second direction DR2 may be a thickness direction of the display device DD.

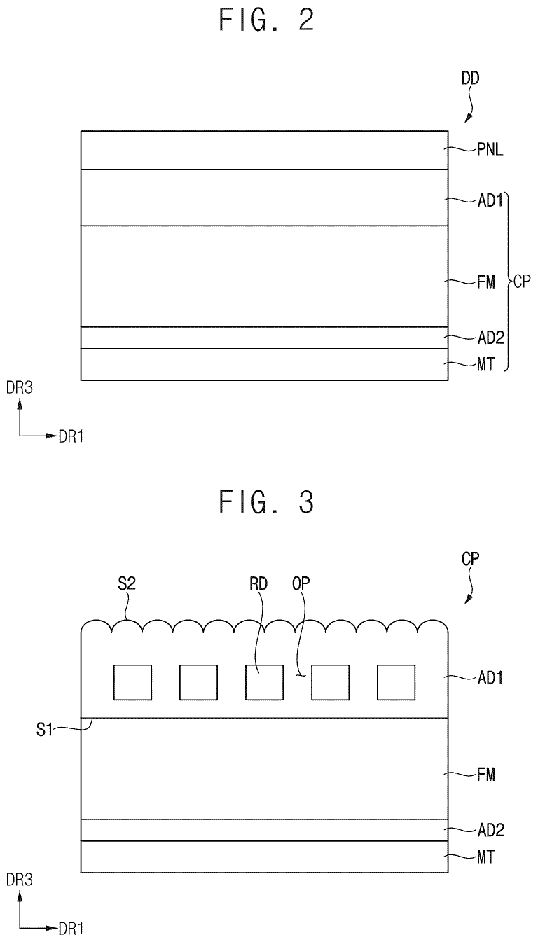

FIG. 2 is a cross-sectional view illustrating a stacked structure of the display device of FIG. 1. FIG. 3 is a cross-sectional view illustrating a panel bottom member (or a panel bottom unit) included in the display device of FIG. 2.

Referring to FIG. 2, in an embodiment, the display device DD may include a display panel PNL including the plurality of pixels. In an embodiment, for example, the display panel PNL may include a pixel (for example, the pixel PX of FIG. 1). Each of the plurality of pixels may emit light.

In an embodiment, the display device DD may include a panel bottom member CP disposed under the display panel PNL. The panel bottom member CP may include a first adhesive layer AD1, a base layer FM, a second adhesive layer AD2, and a metal layer MT.

The base layer FM may be disposed under the display panel PNL. The base layer FM may alleviate an impact applied to a lower surface of the display panel PNL. In an embodiment, for example, the base layer FM may include an acrylic-based foam material, a urethane-based foam material, or the like. These materials may be used alone or in combination with each other.

The first adhesive layer AD1 may be disposed on the base layer FM. In an embodiment, for example, the first adhesive layer AD1 may be disposed between the display panel PNL and the base layer FM. The first adhesive layer AD1 may provide adhesive force to the lower surface of the display panel PNL.

The metal layer MT may be disposed under the base layer FM. The metal layer MT may protect the lower surface of the display panel PNL. In addition, the metal layer MT may dissipate heat generated from the display panel PNL. In an embodiment, for example, the metal layer MT may include copper. However, this disclosure is not limited thereto, and the metal layer MT may include a different type of metal material from copper.

The second adhesive layer AD2 may be disposed between the base layer FM and the metal layer MT. The second adhesive layer AD2 may provide adhesive force to a lower surface of the base layer FM. In an embodiment, for example, the second adhesive layer AD2 may include an optical clear adhesive (“OCA”), an optical clear resin (“OCR”), a pressure sensitive adhesive (“PSA”), or the like. These materials may be used alone or in combination with each other.

Referring further to FIG. 3, the first adhesive layer AD1 may include a first surface S1 and a second surface S2. The first surface S1 may face the base layer FM. The second surface S2 may face the display panel PNL. That is, the second surface S2 may be a surface opposite to the first surface S1. In an embodiment, for example, the second surface S2 may be spaced apart from the first surface S1 in the third direction DR3.

The first adhesive layer AD1 may include an embossing pattern defined on the second surface S2 thereof. In an embodiment, for example, the embossing pattern may protrude toward the display panel PNL. That is, the embossing pattern may protrude in the third direction DR3. Since the first adhesive layer AD1 includes the embossing pattern on the second surface S2, bubbles may not be generated when the panel bottom member CP adheres to a lower portion of the display panel PNL.

In an embodiment, the first adhesive layer AD1 may include a resin material. The resin material may include an acrylic resin, an epoxy resin, a silicone resin, or the like. These materials may be used alone or in combination with each other. However, this disclosure is not limited thereto, and the first adhesive layer AD1 may include other types of resin materials.

In an embodiment, the first adhesive layer AD1 may further include a light-blocking material. The light-blocking material may be uniformly dispersed in the resin material. That is, the light-blocking material may be uniformly dispersed in the resin material through a disperser or the like. In an embodiment, for example, the disperser may include a high frequency disperser or the like.

In an embodiment, the light-blocking material may include a black pigment, a black dye, or the like. In an embodiment, for example, the light-blocking material may include carbon black. Since the first adhesive layer AD1 includes the light-blocking material, the first adhesive layer AD1 may have light-blocking performance. In an embodiment, for example, the first adhesive layer AD1 may reduce an amount of light incident on the lower surface of the display panel PNL.

In an embodiment, a content of the light-blocking material in the first adhesive layer AD1 may be about 1.5 weight percent or greater and about 2 weight percent or less. When the content of the light-blocking material in the first adhesive layer AD1 is less than about 1.5 weight percent, the light-blocking performance of the first adhesive layer AD1 may be reduced. Accordingly, the first adhesive layer AD1 may not sufficiently reduce the amount of light incident on the lower surface of the display panel PNL. When the content of the light-blocking material in the first adhesive layer AD1 exceeds about 2 weight percent, the first adhesive layer AD1 may not provide sufficient adhesion to the lower surface of the display panel PNL. Accordingly, the panel bottom member CP may not be properly attached to the lower surface of the display panel PNL.

In an embodiment, an optical density of the first adhesive layer AD1 may be about 3.0 or greater. The higher the optical density, the lower light transmittance may be. In an embodiment, for example, the optical density of the first adhesive layer AD1 may be determined by the content of the light-blocking material in the first adhesive layer AD1. That is, as the content of the light blocking-material in the first adhesive layer AD1 is about 1.5 weight percent or greater, the optical density of the first adhesive layer AD1 may be about 3.0 or greater.

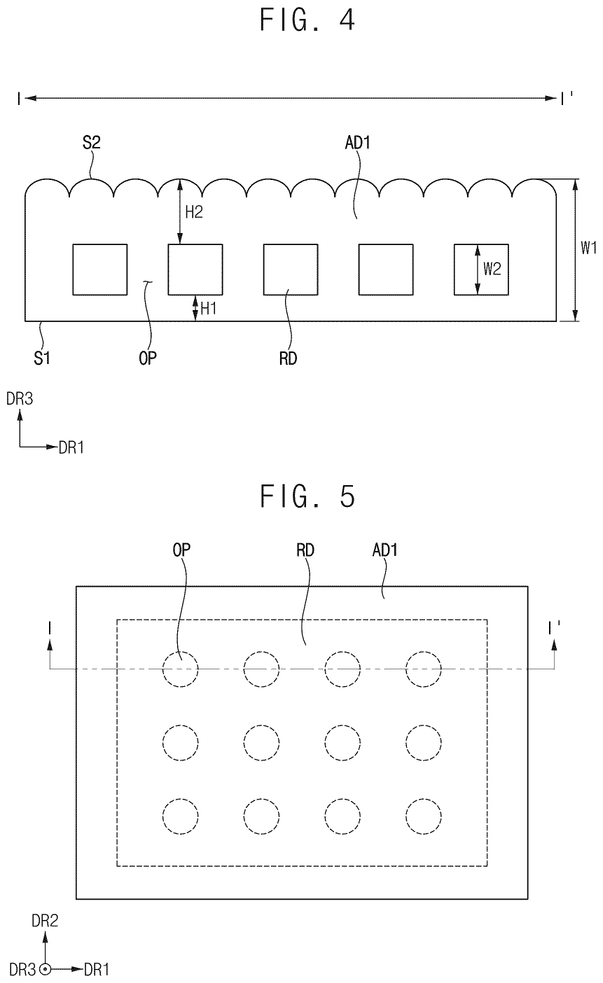

In an embodiment, for example, a thickness of the first adhesive layer AD1 in the third direction DR3 (for example, a thickness W1 of FIG. 4) may be about 50 micrometers or greater and about 70 micrometers or less. In one embodiment, for example, the thickness of the first adhesive layer AD1 may be about 60 micrometers. However, this is only an example, and the thickness of the first adhesive layer AD1 may be variously changed.

FIG. 4 is a cross-sectional view illustrating a first adhesive layer included in the panel bottom member of FIG. 3. FIG. 5 is a plan view illustrating the first adhesive layer of FIG. 4. Specifically, FIG. 4 is a cross-sectional view of the first adhesive layer of FIG. 5 taken along line I-I′.

Referring to FIGS. 4 and 5, in an embodiment, a heat dissipation layer RD may be disposed inside the first adhesive layer AD1. The heat dissipation layer RD may be spaced apart from each of the first surface S1 and second surface S2 of the first adhesive layer AD1 in a cross-sectional view. In an embodiment, for example, the heat dissipation layer RD may be spaced apart from the first surface S1 of the first adhesive layer AD1 in the third direction DR3. In addition, the heat dissipation layer RD may be spaced apart from the second surface S2 of the first adhesive layer AD1 in a direction opposite to the third direction DR3.

In an embodiment, a distance H1 between the heat dissipation layer RD and the first surface S1 of the first adhesive layer AD1 may be less than a distance H2 between the heat dissipation layer RD and the second surface S2 of the first adhesive layer AD1. That is, the heat dissipation layer RD may be disposed closer to the first surface S1 than the second surface S2 of the first adhesive layer AD1.

The heat dissipation layer RD may include a lower surface facing the first surface S1 of the first adhesive layer AD1 and an upper surface facing the second surface S2 of the first adhesive layer AD1. The distance H1 between the heat dissipation layer RD and the first surface S1 of the first adhesive layer AD1 may be a distance between the lower surface of the heat dissipation layer RD and the first surface S1 of the first adhesive layer AD1. In addition, the distance H2 between the heat dissipation layer RD and the second surface S2 of the first adhesive layer AD1 may be a distance between the upper (or uppermost) surface of the heat dissipation layer RD and the second surface S2 of the first adhesive layer AD1. Specifically, the distance H2 between the heat dissipation layer RD and the second surface S2 of the first adhesive layer AD1 may be a distance between the upper surface of the heat dissipation layer RD and a portion of the second surface S2 of the first adhesive layer AD1 that protrudes most in the third direction DR3.

However, this disclosure is not limited thereto, and in another embodiment, the distance H1 between the heat dissipation layer RD and the first surface S1 of the first adhesive layer AD1 may be greater than the distance H2 between the heat dissipation layer RD and the second surface S2 of the first adhesive layer AD1. In such an embodiment, the heat dissipation layer RD may be disposed closer to the second surface S2 than the first surface S1 of the first adhesive layer AD1.

In an embodiment, the heat dissipation layer RD may define a plurality of openings OP. In an embodiment, for example, each of the plurality of openings OP may be an empty (or removed) portion extending from the upper surface of the heat dissipation layer RD to the lower surface of the heat dissipation layer RD. The plurality of openings OP may be repeatedly disposed in the first direction DR1 and the second direction DR2. The first adhesive layer AD1 may fill the plurality of openings OP.

In an embodiment, each of the plurality of openings OP may have a shape of a circle in a plan-view or when viewed in the third direction DR3. However, this disclosure is not limited thereto, and each of the plurality of openings OP may have various shapes such as a polygonal shape, an elliptical shape, or the like, in a plan-view.

In an embodiment, each of the plurality of openings OP may have a rectangular shape in cross-sectional view. However, this disclosure is not limited thereto, and each of the plurality of openings OP may have various shapes such as a tapered shape and an inverted tapered shape, or the like, in cross-sectional view.

In an embodiment, for example, a thickness W2 of the heat dissipation layer RD in the third direction DR3 may be about 10 micrometers or greater and about 20 micrometers or less. In one embodiment, for example, the thickness W2 of the heat dissipation layer RD may be about 17 micrometers. However, this is only an example and the thickness W2 of the heat dissipation layer RD may be variously changed.

In an embodiment, the heat dissipation layer RD may include graphite. However, this disclosure is not limited thereto, and the heat dissipation layer RD may include various materials such as a metal material such as aluminum.

In an embodiment, since the heat dissipation layer RD is disposed inside the first adhesive layer AD1, the first adhesive layer AD1 may dissipate heat generated from the display panel (for example, the display panel PNL of FIG. 2).

In an embodiment, as described above, the first adhesive layer AD1 may have light-blocking performance. In addition, the first adhesive layer AD1 may dissipate heat generated from the display panel. That is, the first adhesive layer AD1 according to an embodiment may have both light-blocking performance and heat dissipation characteristics. Accordingly, in such an embodiment, a plurality of stacked structures for light-blocking performance and heat dissipation characteristics of the panel bottom member (e.g., the panel bottom member CP of FIG. 3) may be omitted. Accordingly, a structure of the panel bottom member may be simplified, and manufacturing cost of the panel bottom member may be reduced.

However, this disclosure is not limited thereto, and in another embodiment, the heat dissipation layer RD may be omitted. That is, the heat dissipation layer RD may not be disposed inside the first adhesive layer AD1.

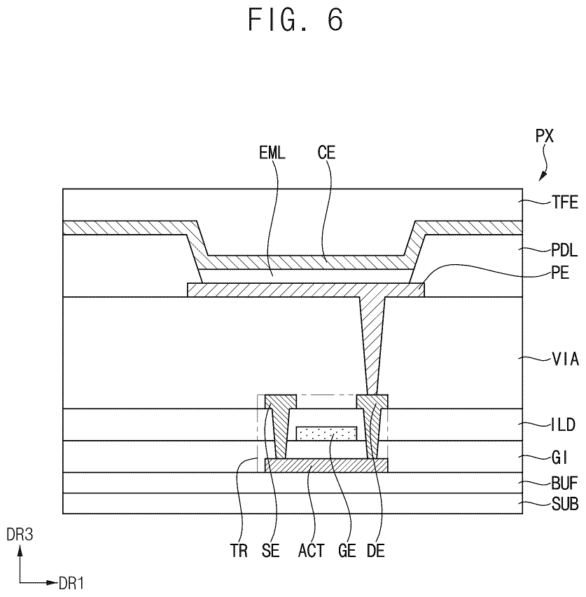

FIG. 6 is a cross-sectional view illustrating a pixel of FIG. 1.

Referring to FIG. 6, the pixel PX may include (or be defined by) a substrate SUB, a buffer layer BUF, a gate insulating layer GI, an interlayer insulating layer ILD, a via insulating layer VIA, an active layer ACT, a source electrode SE, a gate electrode GE, a drain electrode DE, a pixel electrode PE, a pixel defining layer PDL, a light emitting layer EML, a common electrode CE, and an encapsulating layer TFE.

A transistor TR may include (or be defined by) the active layer ACT, the source electrode SE, the gate electrode GE, and the drain electrode DE.

The substrate SUB may include a transparent material or an opaque material. The substrate SUB may include or be formed of a transparent resin substrate. Example of the transparent resin substrate may include a polyimide substrate. In this case, the polyimide substrate may include a first organic layer, a first barrier layer, a second organic layer, or the like.

Alternatively, the substrate SUB may include a quartz substrate (e.g. a synthetic quartz substrate,, a fluorine-doped quartz substrate), a calcium fluoride substrate, a sodalime substrate, a non-alkali glass substrate, or the like. These materials may be used alone or in combination with each other.

The buffer layer BUF may be disposed on the substrate SUB. The buffer layer BUF may prevent metal atoms or impurities from diffusing from the substrate SUB to the transistor TR. In addition, the buffer layer BUF can improve the flatness of a surface of the substrate SUB when the surface of the substrate SUB is not uniform.

In an embodiment, for example, the buffer layer BUF may include an inorganic material such as silicon oxide, silicon nitride, silicon oxynitride, or the like. These materials may be used alone or in combination with each other.

The active layer ACT may be disposed on the buffer layer BUF. The active layer ACT may include an inorganic semiconductor (e.g., amorphous silicon, polysilicon, a metal oxide semiconductor,), an organic semiconductor, and the like. These materials may be used alone or in combination with each other. The active layer ACT may include a source area, a drain area, and a channel area disposed between the source area and the drain area.

The metal oxide semiconductor may include a binary compound (ABₓ), a ternary compound (ABₓC_{y}), a tetragonal compound (ABₓC_{y}D_{z}), and the like including indium (In), zinc (Zn), gallium (Ga), tin (Sn), titanium (Ti), aluminum (Al), hafnium (Hf), zirconium (Zr), magnesium (Mg), or the like.

In an embodiment, for example, the metal oxide semiconductor may include zinc oxide (ZnOₓ), gallium oxide (GaOₓ), tin oxide (SnOₓ), indium oxide (InOₓ), indium gallium oxide (“IGO”), indium zinc oxide (“IZO”), indium tin oxide (“ITO”), indium zinc tin oxide (“IZTO”), and indium gallium zinc oxide (“IGZO”). These materials may be used alone or in combination with each other.

The gate insulating layer GI may be disposed on the buffer layer BUF. The gate insulating layer GI may sufficiently cover the active layer ACT, and may have a substantially flat upper surface without generating a step around the active layer ACT. Alternatively, the gate insulating layer GI may cover the active layer ACT and may be disposed along a profile of the active layer ACT.

In an embodiment, for example, the gate insulating layer GI may include inorganic materials such as silicon oxide (SiOₓ), silicon nitride (SiNₓ), silicon carbide (SiCₓ), silicon oxynitride (SiOₓN_{y}), silicon oxycarbide (SiOₓC_{y}), or the like. These materials may be used alone or in combination with each other.

The gate electrode GE may be disposed on the gate insulating layer GI. The gate electrode GE may overlap the channel area of the active layer ACT.

The gate electrode GE may include a metal, an alloy metal nitride, a conductive metal oxide, a transparent conductive material, or the like. Examples of the metal may include silver (Ag), molybdenum (Mo), aluminum (Al), tungsten (W), copper (Cu), nickel (Ni), chromium (Cr), titanium (Ti), tantalum (Ta), platinum (Pt), scandium (Sc), or the like. These materials may be used alone or in combination with each other.

Examples of the conductive metal oxide may include Indium tin oxide, indium zinc oxide, or the like. In addition, examples of the metal nitride may include aluminum nitride (AlNₓ), tungsten nitride (WNₓ), chromium nitride (CrNₓ), or the like. These materials may be used alone or in combination with each other.

The interlayer insulating layer ILD may be disposed on the gate insulating layer GI. The interlayer insulating layer ILD may sufficiently cover the gate electrode GE, and may have a substantially flat upper surface without generating a step around the gate electrode GE. Alternatively, the interlayer insulating layer ILD may cover the gate electrode GE, and may be disposed along a profile of the gate electrode GE.

In an embodiment, for example, the interlayer insulating layer ILD may include inorganic materials such as silicon oxide, silicon nitride, silicon carbide, silicon oxynitride, silicon oxycarbide, or the like. These materials may be used alone or in combination with each other.

The source electrode SE may be disposed on the interlayer insulating layer ILD. The source electrode SE may be connected to the source area of the active layer ACT through a contact hole defined through the gate insulating layer GI and the interlayer insulating layer ILD.

The drain electrode DE may be disposed on the interlayer insulating layer ILD. The drain electrode DE may be connected to the drain area of the active layer ACT through a contact hole defined through the gate insulating layer GI and the interlayer insulating layer ILD.

In an embodiment, for example, the source electrode SE may include a metal, an alloy, a metal nitride, a conductive metal oxide, a transparent conductive material, and the like. These materials may be used alone or in combination with each other. The drain electrode DE may be formed through a same process as the source electrode SE and may include a same material as the source electrode SE.

The via insulating layer VIA may be disposed on the interlayer insulating layer ILD. The via insulating layer VIA may sufficiently cover the source electrode SE and the drain electrode DE. The via insulating layer VIA may include an organic material. For example, the via insulating layer VIA may include organic materials such as phenolic resin, acrylic resin, polyimide resin, polyamide resin, siloxane resin, epoxy resin, or the like. These materials may be used alone or in combination with each other.

The pixel electrode PE may be disposed on the via insulating layer VIA. The pixel electrode PE may be connected to the drain electrode DE through a contact hole defined through the via insulating layer VIA.

The pixel electrode PE may include a metal, an alloy, a metal nitride, a conductive metal oxide, a transparent conductive material, or the like. These materials be used alone or in combination with each other. In an embodiment, the pixel electrode PE may have a stacked structure including ITO/Ag/ITO. In an embodiment, for example, the pixel electrode PE may operate as an anode.

The pixel defining layer PDL may be disposed on the via insulating layer VIA. The pixel defining layer PDL may cover side portions of the pixel electrode PE. In addition, an opening exposing a portion of the upper surface of the pixel electrode PE may be defined in the pixel defining layer PDL.

In an embodiment, for example, the pixel defining layer PDL may include an inorganic material or an organic material. In an embodiment, the pixel defining layer PDL may include an organic material such as an epoxy resin, a siloxane resin, or the like. These materials may be used alone or in combination with each other. In another embodiment, the pixel defining layer PDL may further include a light blocking material containing a black pigment, a black dye, or the like.

The light emitting layer EML may be disposed on the pixel electrode PE. The light emitting layer EML may include an organic material that emits light of a predetermined color. In an embodiment, for example, the light emitting layer EML may include an organic material that emits red light. However, the present disclosure is not limited thereto, and the light emitting layer EML may emit light of a different color from red light.

The common electrode CE may be disposed on the light emitting layer EML and the pixel defining layer PDL. The common electrode CE may include a metal, an alloy, a metal nitride, a conductive metal oxide, a transparent conductive material, or the like. These materials may be used alone or in combination with each other. The common electrode CE may operate as a cathode.

The encapsulation layer TFE may be disposed on the common electrode CE. The encapsulation layer TFE may prevent impurities and moisture from penetrating into the pixel electrode PE, the light emitting layer EML, and the common electrode CE from the outside. The encapsulation layer TFE may include at least one inorganic layer and at least one organic layer.

In an embodiment, for example, the inorganic layer may include silicon oxide, silicon nitride, silicon oxynitride, or the like. These materials may be used alone or in combination with each other. The organic layer may include a polymer cured product such as polyacrylate.

Although an embodiment of the pixel PX is described above with reference to FIG. 6, the pixel PX is not limited to the structure shown in FIG. 6. That is, the pixel PX may include any structure that receive an electrical signal and emit light having a luminance corresponding to the intensity of the electrical signal.

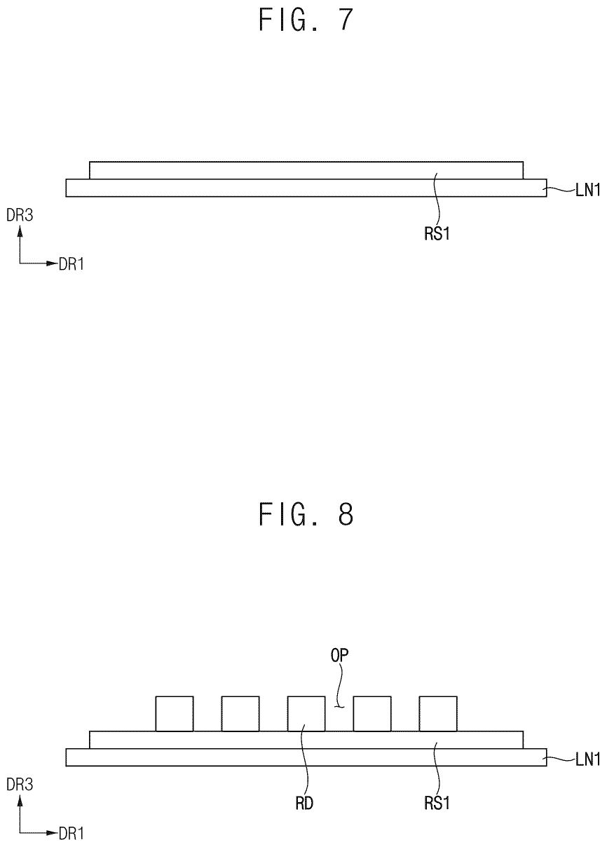

FIGS. 7, 8, 9, 10, 11, 12, 13, and 14 are cross-sectional views illustrating an embodiment of a method for manufacturing the display device of FIG. 2.

Referring to FIG. 7, a first adhesive resin layer RS1 may be provided or formed on a first release film LN1. In an embodiment, for example, the first release film LN1 may include silicon or fluorine. These materials be used alone or in combination with each other. In an embodiment, for example, the first adhesive resin layer RS1 may include an acrylic resin, an epoxy resin, a silicone resin, or the like. These materials may be used alone or in combination with each other.

In an embodiment, the first adhesive resin layer RS1 may further include a light-blocking material. The light-blocking material may be uniformly dispersed in the first adhesive resin layer RS1. The light-blocking material may include a black pigment, a black dye, or the like. The light-blocking material may include carbon black.

Referring to FIG. 8, the heat dissipation layer RD may be provided or formed on the first adhesive resin layer RS1. The heat dissipation layer RD may define the plurality of openings OP or the plurality of openings OP may be formed through the heat dissipation layer RD. In an embodiment, for example, the heat dissipation layer RD may include graphite.

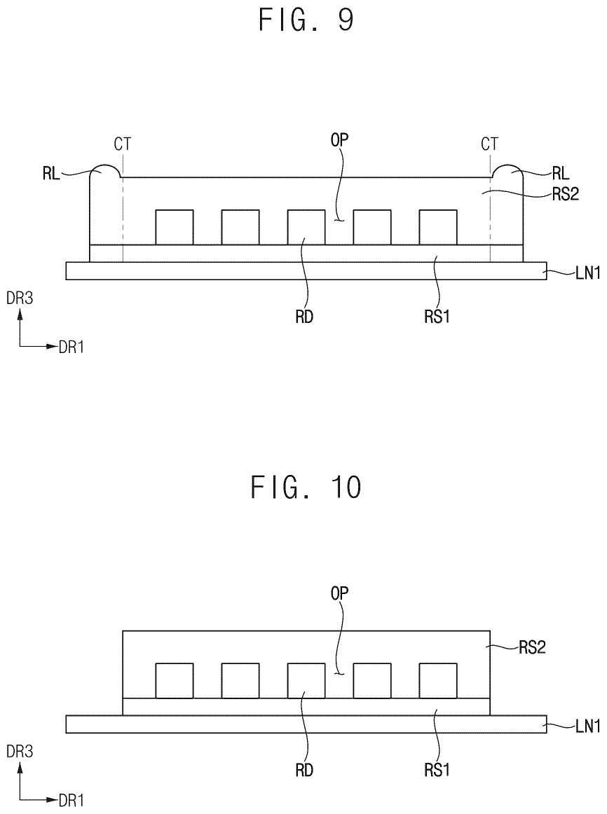

Referring to FIG. 9, a second adhesive resin layer RD2 may be provided or formed on the first adhesive resin layer RS1. The second adhesive resin layer RD2 may be formed to cover the heat dissipation layer RD. In an embodiment, for example, the second adhesive resin layer RD2 may fill the plurality of openings OP. In an embodiment, for example, the second adhesive resin layer RS2 may include an acrylic resin, an epoxy resin, a silicone resin, or the like. These materials may be used alone or in combination with each other.

In an embodiment, the second adhesive resin layer RS2 may further include a light-blocking material. The light-blocking material may be uniformly dispersed in the second adhesive resin layer RS2. The light-blocking material may include a black pigment, a black dye, or the like. The light-blocking material may include carbon black.

A bump RL may be provided or formed on an upper surface of the second adhesive resin layer RS2. In an embodiment, for example, the bump RL may be a portion protruding from the upper surface of the second adhesive resin layer RS2 in the third direction DR3. The bump RL may be formed along an edge of the second adhesive resin layer RS2 because the second adhesive resin layer RS2 includes an adhesive material such as an acrylic resin.

Referring to FIGS. 9 and 10, portions of the first adhesive resin layer RS1 and the second adhesive resin layer RS2 may be cut along a cutting line CT to remove the bump RL.

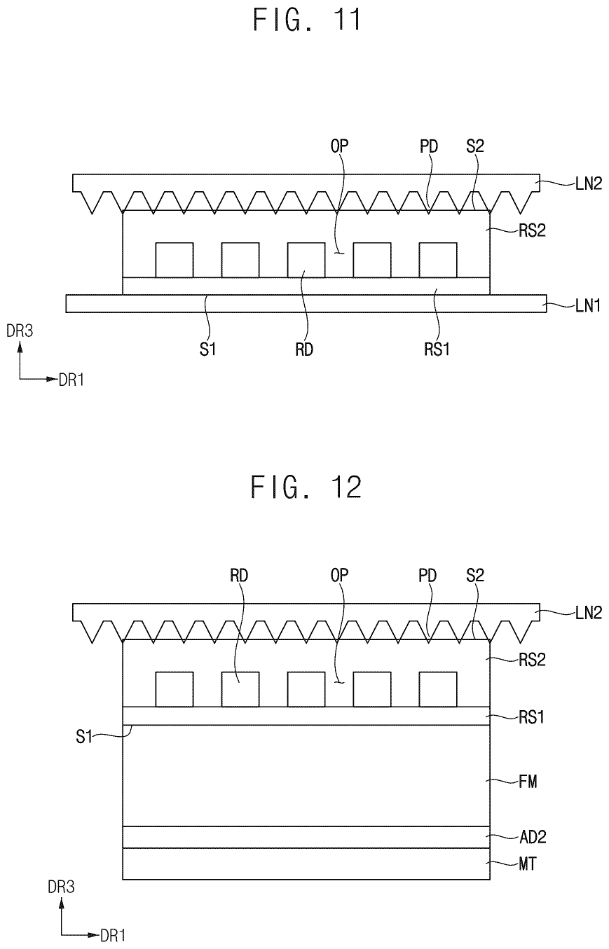

Referring to FIG. 11, a second release film LN2 may be attached on the second adhesive resin layer RS2. In an embodiment, for example, the second release film LN2 may be attached to the second surface S2 of the second adhesive resin layer RS2. The second release film LN2 may include a plurality of protrusions PD. The plurality of protrusions PD may protrude toward the second adhesive resin layer RS2. That is, the plurality of protrusions PD may protrude in a direction opposite to the third direction DR3. In an embodiment, for example, the plurality of protrusions PD may have a triangular shape in a cross-sectional view. In an embodiment, for example, the second release film LN2 may include substantially a same material as the first release film LN1.

The second adhesive resin layer RS2 may be aged in a state in which the second release film LN2 including the plurality of protrusions PD is attached to the second surface S2 of the second adhesive resin layer RS2. In an embodiment, for example, the second adhesive resin layer RS2 may be aged at a temperature of about 50° C. or higher and about 70° C. or lower. In one embodiment, for example, the second adhesive resin layer RS2 may be aged at about 60° C. However, this is only an example, and the second adhesive resin layer RS2 may be aged at various temperatures.

In an embodiment, for example, the second adhesive resin layer RS2 may be aged under a pressure of about 0.1 bar or greater and about 0.5 bar or less. In one embodiment, for example, the second adhesive resin layer RS2 may be aged under a pressure of about 0.3 bar. However, this is only an example, and the second adhesive resin layer RS2 may be aged under various pressures.

In an embodiment, for example, the second adhesive resin layer RS2 may be aged for about 48 hours to about 96 hours. In one embodiment, for example, the second adhesive resin layer RS2 may be aged for about 72 hours. However, this is only an example, and the aging time of the second adhesive resin layer RS2 may be variously set.

As the second adhesive resin layer RS2 is aged, the embossing pattern may be formed on the second surface S2 of the second adhesive resin layer RS2.

Referring to FIGS. 11 and 12, after the first release film LN1 is removed, the base layer FM may be provided or formed on a lower portion of the first adhesive resin layer RS1. In an embodiment, for example, the base layer FM may be attached to the first surface S1 of the first adhesive resin layer RS1. In an embodiment, for example, the base layer FM may include an acrylic foam material or a urethane foam material.

The second adhesive layer AD2 may be provided or formed under the base layer FM. The second adhesive layer AD2 may provide adhesive force to the lower surface of the base layer FM. In an embodiment, for example, the second adhesive layer AD2 may include an OCA, an OCR, a PSA, or the like. These materials may be used alone or in combination with each other.

The metal layer MT may be provided or formed under the second adhesive layer AD2. The metal layer MT may include a metal material such as copper.

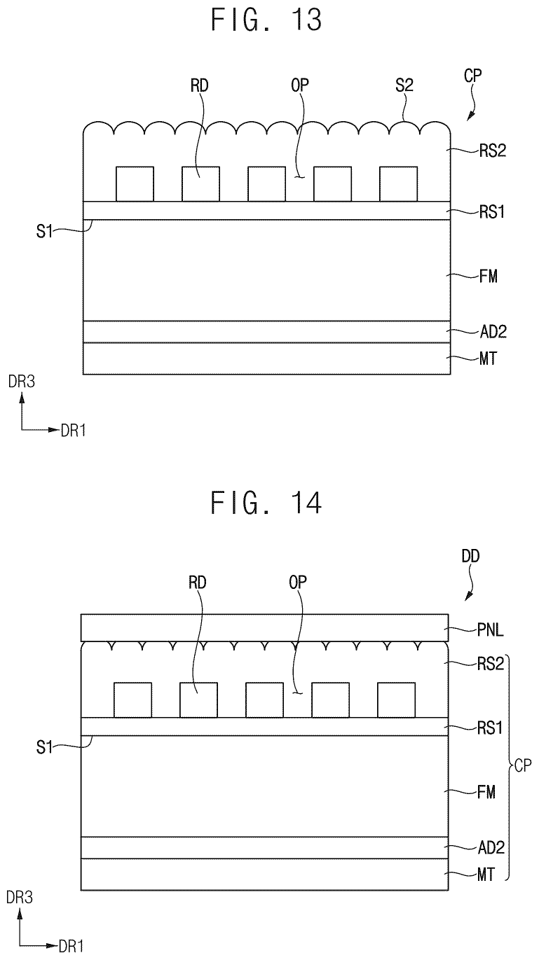

Referring to FIG. 13, the second release film LN2 may be removed such that an embossing pattern may be formed on the second surface S2 of the second adhesive resin layer RS2 (or may be exposed). The first adhesive layer AD1 of FIG. 3 may include the first adhesive resin layer RS1 and the second adhesive resin layer RS2 of FIG. 13.

Accordingly, the panel bottom member CP including the first adhesive layer, the heat dissipation layer RD, the base layer FM, the second adhesive layer AD2, and the metal layer MT may be formed.

Referring to FIG. 14, the panel bottom member CP may be attached to the lower portion of the display panel PNL. Accordingly, the display device DD may be formed.

Embodiments of the disclosure may be applied to various display devices such as display devices for vehicles, ships and aircraft, portable communication devices, display devices for exhibition or information transmission, medical display devices, or the like.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A panel bottom member comprising:
a base layer;
a first adhesive layer disposed on the base layer, wherein the first adhesive layer includes a light-blocking material, a first surface of the first adhesive layer faces the base layer, and an embossing pattern is defined on a second surface of the first adhesive layer which is opposite to the first surface; and
a heat dissipation layer disposed in the first adhesive layer.

2. The panel bottom member of claim 1, wherein
a plurality of openings are defined in the heat dissipation layer, and
the first adhesive layer fills the plurality of openings of the heat dissipation layer.

3. The panel bottom member of claim 1, wherein the heat dissipation layer includes graphite.

4. The panel bottom member of claim 1, wherein the heat dissipation layer is spaced apart from each of the first surface of the first adhesive layer and the second surface of the first adhesive layer in cross-sectional view.

5. The panel bottom member of claim 4, wherein a distance between the heat dissipation layer and the first surface of the first adhesive layer is less than a distance between the heat dissipation layer and the second surface of the first adhesive layer.

6. The panel bottom member of claim 1, wherein the light-blocking material includes carbon black.

7. The panel bottom member of claim 1, wherein a content of the light-blocking material in the first adhesive layer is about 1.5 weight percent or greater and about 2 weight percent or less.

8. The panel bottom member of claim 1, wherein an optical density of the first adhesive layer is about 3.0 or greater.

9. The panel bottom member of claim 1, wherein the base layer includes an acrylic foam material or a urethane-based foam material.

10. The panel bottom member of claim 1, further comprising:
a metal layer disposed under the base layer; and
a second adhesive layer disposed between the base layer and the metal layer.

11. The panel bottom member of claim 10, wherein the metal layer includes copper.

12. A display device comprising:
a display panel including a plurality of pixels; and
a panel bottom member disposed under the display panel,
wherein the panel bottom member includes:
a base layer;
a first adhesive layer disposed between the base layer and the display panel, wherein the first adhesive layer includes a light-blocking material, a first surface of the first adhesive layer faces the base layer, and an embossing pattern is defined on a second surface of the first adhesive layer which is opposite to the first surface; and
a heat dissipation layer disposed in the first adhesive layer.

13. The display device of claim 12, wherein
a plurality of openings are defined in the heat dissipation layer,
the first adhesive layer fills the plurality of openings of the heat dissipation layer, and
the heat dissipation layer is spaced apart from each of the first surface of the first adhesive layer and the second surface of the first adhesive layer in cross-sectional view.

14. A method for manufacturing a display device, the method comprising:
forming a panel bottom member; and
attaching the panel bottom member to a lower portion of a display panel,
wherein the forming the panel bottom member includes:
forming a heat dissipation layer, in which a plurality of openings are defined, on a first adhesive resin layer;
forming a second adhesive resin layer on the first adhesive resin layer to cover the heat dissipation layer;
forming an embossing pattern on an upper surface of the second adhesive resin layer; and
forming a base layer under the first adhesive resin layer.

15. The method of claim 14, wherein each of the first adhesive resin layer and the second adhesive resin layer includes a light-blocking material.

16. The method of claim 14, wherein in the forming the second adhesive resin layer, the second adhesive resin layer fills the plurality of openings of the heat dissipation layer.

17. The method of claim 14, wherein
the first adhesive resin layer is formed on a first release film, and
the forming the base layer under the first adhesive resin layer includes attaching the base layer to a lower portion of the first adhesive resin layer after removing the first release film from the first adhesive resin layer.

18. The method of claim 14, wherein the forming the embossing pattern on the upper surface of the second adhesive resin layer includes attaching a second release film including a plurality of protrusions protruding toward the second adhesive resin layer to the second adhesive resin layer.

19. The method of claim 18, wherein the forming the embossing pattern on the upper surface of the second adhesive resin layer further includes aging the second adhesive resin layer, to which the second release film is attached, for a preset period.

20. The method of claim 18, wherein the forming the embossing pattern on the upper surface of the second adhesive resin layer further includes removing the second release film from the second adhesive resin layer before the attaching the panel bottom member to the lower portion of the display panel.
